(19) United States
(12) Patent Application Publication
(10) Pub. No.: US 2016/0380014 A1
(43) Pub. Date: Dec. 29, 2016

(54) Thermal Imaging Device

(71) Applicant: INVIS TECHNOLOGIES CORPORATION, Santa Clara, CA (US)

(72) Inventors: Srinivasan K. Ganapathi, Palo Alto, CA (US); Philip J. Stephanou, Mountain View, CA (US); Kurt E. Petersen, Milpitas, CA (US)

(73) Assignee: INVIS TECHNOLOGIES CORPORATION, Santa Clara, CA (US)

(21) Appl. No.: 14/210,276

(22) Filed: Mar. 13, 2014

Related U.S. Application Data
(60) Provisional application No. 61/932,014, filed on Jan. 27, 2014.

(51) Int. Cl. H01L 27/146; G02B 13/00; G02B 3/00; H04N 5/33; H04N 5/378

(52) U.S. Cl. CPC H01L 27/14627; H04N 5/33; H04N 5/378; G02B 3/0056; G02B 13/0085; G02B 13/008; G02B 3/0075; H01L 27/14605; H01L 27/14649; H01L 27/14618

(57) ABSTRACT

A thermal imaging device comprises a focal plane array disposed on a focal plane substrate. The focal plane array comprises a plurality of pixels grouped into sub-arrays of pixels. The device also comprises a lens array comprising a plurality of lenslets. Each of the lenslets is arranged to focus infrared rays on a respective one of the sub-arrays of pixels. The focal plane array is enclosed in a vacuum in a space between the lens array and the focal plane substrate, and a readout circuit is electrically connected to the pixels. The thermal imaging device has a small form factor and low cost while maintaining adequate performance, enabling expanded usage of thermal imaging (e.g., in security, surveillance, first responder, defense and/or automotive applications).

### CROSS REFERENCE TO RELATED APPLICATIONS

This application claims the benefit of U.S. provisional patent application 61/932,014 filed on Jan. 27, 2014, titled “Improved Packaging and Optical System Design for Micro-Bolometer Array”, which application is hereby incorporated by reference in its entirety.

### BACKGROUND

The invention relates to thermal imaging devices, and in particular to an imaging device having an improved vacuum package and optical system design.

Many existing thermal imaging solutions for night vision are based on uncooled micro-bolometer arrays that are sensitive to long wavelength infrared (LWIR) radiation in the wavelength range of about 8 to 12 μm. The infrared (IR) camera typically includes a camera core comprising a Focal Plane Array (FPA) and a lens system. The FPA typically comprises three elements—the underlying Read-Out Integrated Circuit (ROIC), the thermistor or micro-bolometer pixel array which is built on top of the ROIC, usually on the same silicon wafer and integrated with the ROIC, and a “packaged window” or lid which is substantially transparent to incoming IR radiation from a source and bonded on top of the FPA with a hermetic vacuum seal. Finally, a single lens or a system of lenses is mounted on top of the FPA.

Traditionally, the approach chosen to enable vacuum has been to use a crystalline germanium lid, and bond it to the FPA package. In order to minimize stresses due to differential coefficients of expansion, the FPA wafer is first singulated into die and mounted on a ceramic package. The germanium lid is then bonded to the ceramic package under very high vacuum. In spite of its high cost, germanium is selected as a lid material because of its low attenuation of infrared light in the relevant range of wavelengths. The approach of singulating a wafer into die, and then individually packaging each die has significant cost implications. Typically, the optical lens system can be quite complex and involve multiple lens elements. In the case of IR imaging optics, the lens material is usually made through diamond point turning of germanium, which can be a very expensive process.

Consequently, many micro-bolometer devices currently available for thermal imaging are bulky, extremely expensive, and largely restricted to special use cases such as military or high-end automotive applications. Many night vision cameras today cost several thousands of dollars apiece, making their integration into mid- and low-range priced applications prohibitive. There is still a need for a night vision thermal imaging camera core that enables a small form factor and low cost while maintaining adequate performance. This would enable usage of thermal imaging in expanded security, surveillance, first responder and automotive applications.

### SUMMARY

According to one aspect, a thermal imaging device comprises a focal plane array disposed on a focal plane substrate. The focal plane array comprises a plurality of pixels grouped into sub-arrays of pixels. A lid substrate is arranged with the focal plane substrate to enclose the focal plane array in a vacuum. The device also includes a lens array comprising a plurality of lenslets. Each of the lenslets is arranged to focus infrared rays on a respective one of the sub-arrays of pixels. Support structures are arranged between the lid substrate and the focal plane substrate to support a portion of the lid substrate through which the infrared rays are transmitted. A readout circuit is electrically connected to the pixels.

According to another aspect, a thermal imaging device comprises a focal plane array disposed on a focal plane substrate. The focal plane array comprises a plurality of pixels grouped into sub-arrays of pixels. The device also comprises a lens array substrate comprising a plurality of lenslets. Each of the lenslets is arranged to focus infrared rays on a respective one of the sub-arrays of pixels. The lens array substrate is arranged with the focal plane substrate to enclose the focal plane array in a vacuum in a space between the lens array substrate and the focal plane substrate. The device further comprises a readout circuit electrically connected to the pixels.

According to another aspect, a scene is imaged by detecting infrared rays with a focal plane array comprising a plurality of pixels formed on a focal plane substrate. The focal plane array is enclosed in a vacuum in a space between a second substrate and the focal plane substrate. The plurality of pixels are grouped into sub-arrays of pixels, and the infrared rays are focused by a lens array comprising a plurality of lenslets. Each of the lenslets is arranged to focus the infrared rays on a respective one of the sub-arrays of pixels. At least one processor is employed to construct an image from pixel signals.

### BRIEF DESCRIPTION OF THE DRAWINGS

The foregoing aspects and advantages of the present invention will become better understood upon reading the following detailed description and upon reference to the drawings where:

FIG. 1 is a schematic, exploded view of a thermal imaging device according to some embodiments of the invention.

FIG. 2 is a schematic, cross-sectional view of a thermal imaging device according to some embodiments of the invention.

FIG. 3 is an isometric, cross-sectional view of a thermal imaging device according to some embodiments of the invention.

FIG. 4 is a top plan view of a pixel array on a wafer.

FIG. 5 is a top plan view of a pixel array divided into sub-arrays of pixels, according to some embodiments of the invention.

FIG. 6 is an isometric, cross-sectional view of a thermal imaging device with a portion of the lid removed to illustrate underlying support structures, according to some embodiments of the invention.

FIG. 7 is an isometric view of support structures on a lid substrate, according to some embodiments of the invention.

FIG. 8 is a top plan view of a micro-lens array and pixel sub-arrays, according to some embodiments of the invention.

FIG. 9 is a partially exploded view of a carrier wafer having arrays of lenslets, according to some embodiments of the invention.

FIG. 10 is a partially exploded view of a carrier wafer having arrays of lenslets, according to another embodiment of the invention.

FIG. 11 is a partially exploded view of a carrier wafer having arrays of lenslets positioned in windows, according to another embodiment of the invention.

FIG. 12 is an isometric view of a wafer of lenslet arrays according to another embodiment of the invention.

FIG. 13 is a block diagram illustrating the imaging of a scene with a multiple lenslet array and reconstruction of the image.

FIG. 14 is a block diagram of a thermal imaging device according to some embodiments of the invention.

FIG. 15 is a schematic, exploded view of a thermal imaging device according to another embodiment of the invention.

FIG. 16 is a schematic, cross-sectional view of the thermal imaging device of FIG. 15.

FIG. 17 is a top plan view of a focal plane substrate according to another embodiment.

FIGS. 18A-18C are schematic, side views of process steps for attaching a lid to an FPA/ROIC wafer, according to some embodiments.

### DETAILED DESCRIPTION OF PREFERRED EMBODIMENTS

In the following description, it is understood that all recited connections between structures can be direct operative connections or indirect operative connections through intermediary structures. A set of elements includes one or more elements. Any recitation of an element is understood to refer to at least one element. A plurality of elements includes at least two elements. Unless otherwise required, any described method steps need not be necessarily performed in a particular illustrated order. A first element (e.g. a signal or data) derived from a second element encompasses a first element equal to the second element, as well as a first element generated by processing the second element and optionally other data. Making a determination or decision according to a parameter encompasses making the determination or decision according to the parameter and optionally according to other data. Unless otherwise specified, an indicator of some quantity/data may be the quantity/data itself, or an indicator different from the quantity/data itself. Computer programs described in some embodiments of the present invention may be stand-alone software entities or sub-entities (e.g., subroutines, code objects) of other computer programs. Computer readable media encompass non-transitory media such as magnetic, optic, and semiconductor storage media (e.g. hard drives, optical disks, flash memory, DRAM), as well as communications links such as conductive cables and fiber optic links According to some embodiments, the present invention provides, inter alia, computer systems comprising hardware (e.g. one or more processors and associated memory) programmed to perform the methods described herein, as well as computer-readable media encoding instructions to perform the methods described herein.

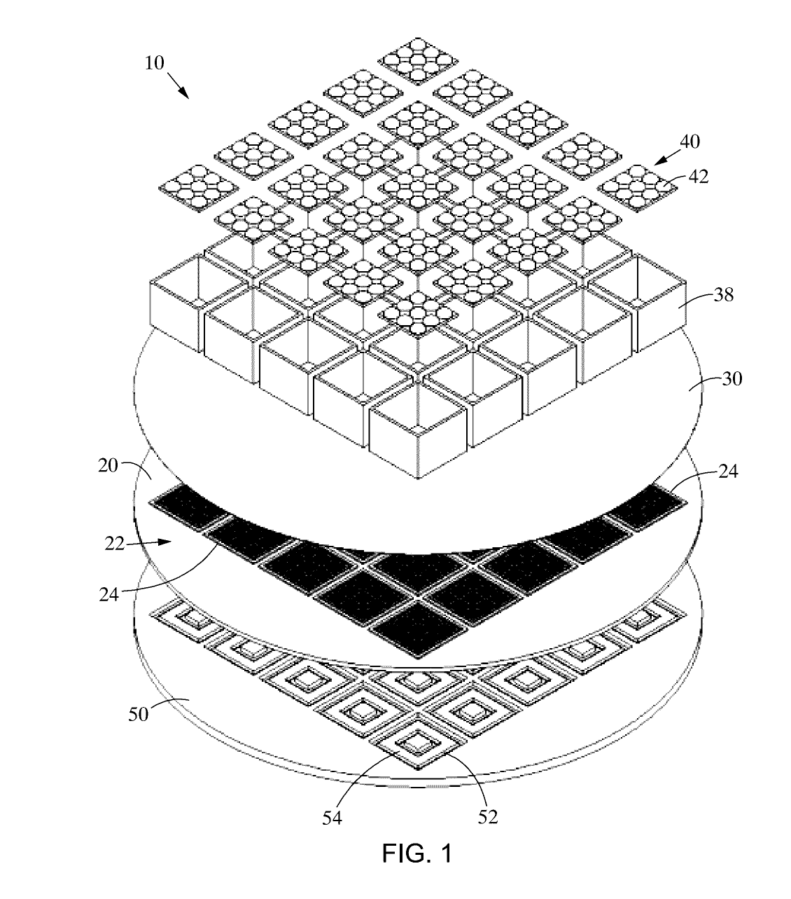

FIG. 1 shows a schematic, exploded view of a thermal imaging device 10 according to some embodiments of the present invention. The device 10 includes a focal plane array (FPA) 22 preferably formed on a wafer or substrate 20. The FPA 22 comprises a plurality of pixels grouped into sub-arrays 24 of pixels. The device 10 also includes a lens array 40 comprising a plurality of micro-lenses or lenslets 42. Each lenslet 42 is arranged to focus infrared rays on a respective one of the sub-arrays 24 of pixels. A spacer or standoff structure 38 may optionally be used to locate the lenslet array 40 at a desired separation from the FPA 22 and to align the optical axes of the lenslets 42 with the respective sub-arrays 24. The separation of the lens array 40 from the FPA 22 preferably provides an optical path length in the range of 2 to 12 mm from each lenslet 42 to the respective sub-array 24 of pixels on which the lenslet focuses the infrared rays. The standoff structure 38 may be patterned, for example, from silicon (e.g., by DRIE of a SOI wafer), a metal, ceramic, or polymer.

A lid substrate 30 encloses the FPA 22 in a vacuum. A readout circuit is electrically connected to the pixels. In some embodiments, a Read-Out Integrated Circuit (ROIC) underlies the FPA 22. Preferably, the FPA 22 is built on top of the ROIC on the same silicon wafer or substrate 20 and integrated with the ROIC. The device 10 optionally includes a cavity substrate 50 attached to the focal plane substrate 20. The cavity substrate 50 has one or more cavities 52 in fluid communication with the sub-arrays 24 by means of vias in the focal plane substrate 20. In some embodiments, the cavities 52 contain getter material 54 to aid in maintaining the vacuum.

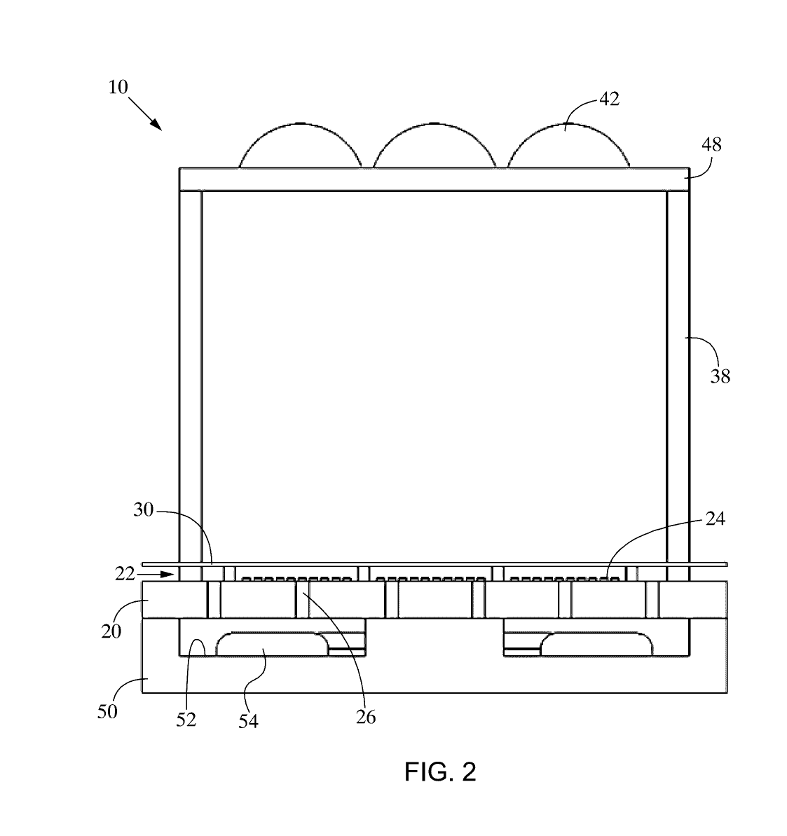

FIG. 2 shows a schematic, cross-sectional view of the thermal imaging device 10. The FPA/ROIC substrate 20 has vias 26 fluidicly connecting the cavities 52 to the sub-arrays 24 of pixels. Once the FPA/ROIC substrate 20 has been fabricated, the FPA 22 is preferably packaged such that it is maintained in a vacuum to minimize heat transfer between the pixels and ambient environment through atmospheric convection. The term vacuum is intended to mean a space in which the pressure is lower than atmospheric pressure. Maintaining a desired level of vacuum (e.g., a pressure in the range of 0.1 to 100 mTorr) may optionally be aided by putting getter material 54 in the cavities 52. The getter material may comprise, for example, an alloy containing zirconium and one or more of vanadium, cobalt, iron, aluminum, or titanium.

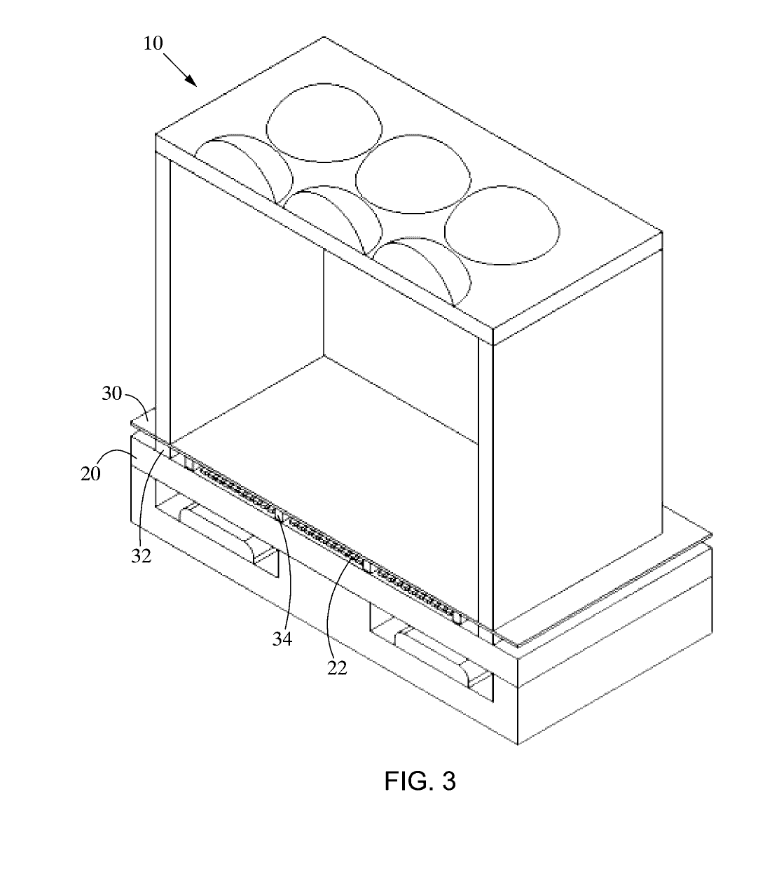

FIG. 3 shows an isometric, cross-sectional view of the thermal imaging device 10. In some embodiments, the lid wafer or substrate 30 comprises a thin (e.g., preferably in the range of 5 to 50 μm) layer of single crystal silicon that is substantially optically transmissive to infrared rays in the wavelength range of 8 to 12 μm. The lid substrate 30 is preferably fusion bonded to the underlying FPA substrate 20. The lid substrate 30 is preferably bonded around the periphery of the FPA 22 by means of a bonding ring 32, and the lid substrate 30 is supported at multiple locations throughout the array by a series of support structures, such as dams or walls 34, positioned between the FPA substrate 20 and the lid substrate 30. These support structures support the portion of the lid substrate 30 through which the infrared rays are transmitted, thus eliminating or reducing excessive “bow” of the thin lid that may otherwise occur as a result of a pressure differential across the lid.

The use of the thin layer of silicon as a lid substrate 30 combined with fusion bonding rather than solder bonding brings three distinct advantages. First, by virtue of the support structures, such as the walls 34, the spacing between the pixels and the lid substrate 30 can be extremely small, which reduces the thickness of the packaged array. Second, the cost of fabricating the lid wafer is significantly lower than a traditional wafer level packaging (WLP) approach. Third, the absorption of the IR through a few μm of the lid is much lower than through the several hundred μm typically encountered in WLP. Compared to solder joining processes, the fusion bond is an inherently lower cost process, and can also result in reduced outgassing, thus improving yield and reliability, and require less area on the die, further reducing cost.

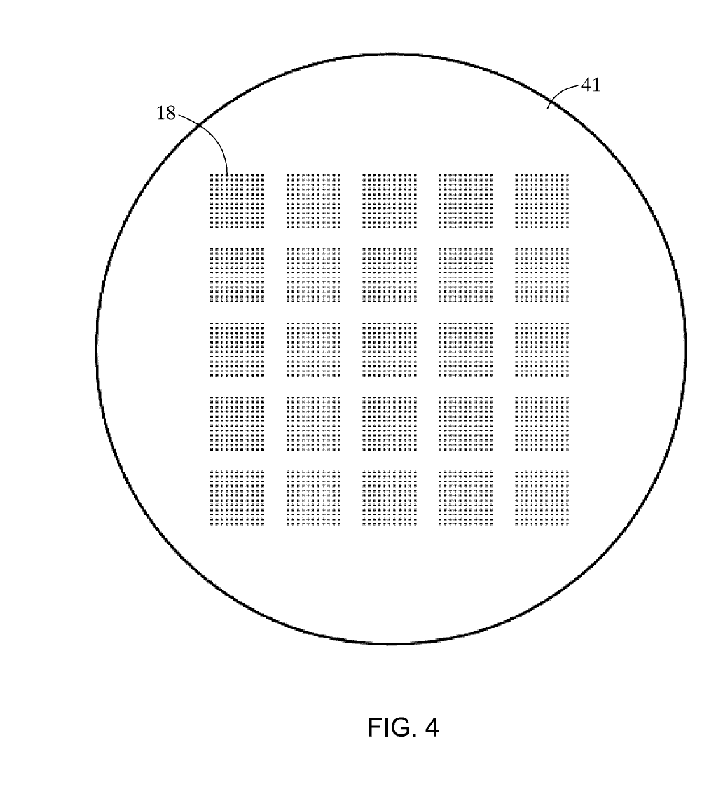

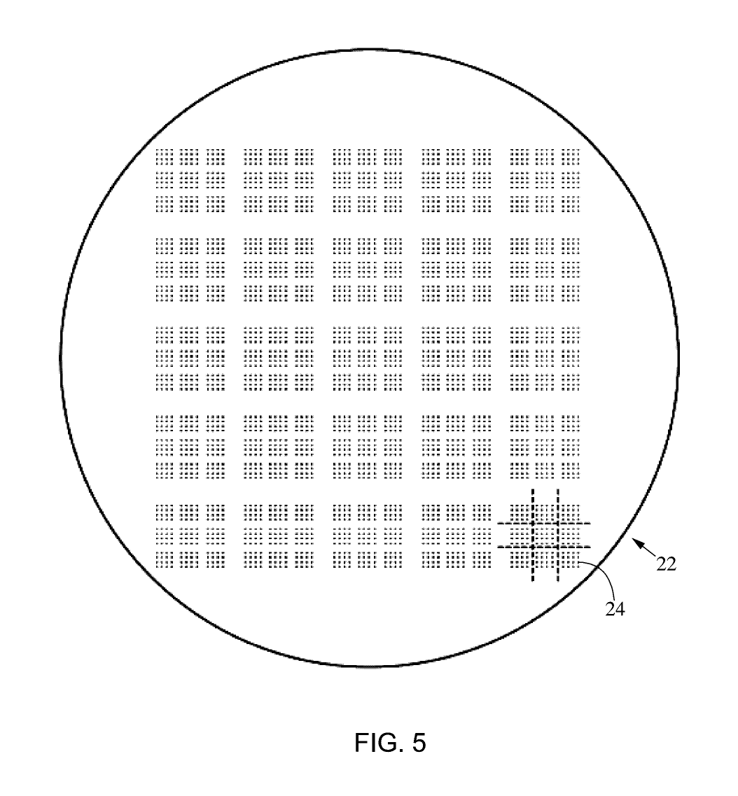

FIG. 4 shows a pixel array 18 on a wafer 41. In some embodiments, the thermal imaging device includes a-Si or VO_{X} MEMS micro-bolometer pixels in, for example, 10 to 25 μm pitch arrays. FIG. 5 shows an example of subdividing an array 22 of pixels into sub-arrays 24 of pixels, in a 3×3 configuration. Other pixel array configurations include, for example, 4×4, 3×4, 4×5, or 5×5 sub-arrays. The modification to the conventional array may be achieved physically by modifying the layout of the array, or functionally by sacrificing pixels along prescribed rows and columns to define inter sub-array exclusion zones. Examples of the exclusion zones are represented by dotted lines in FIG. 5.

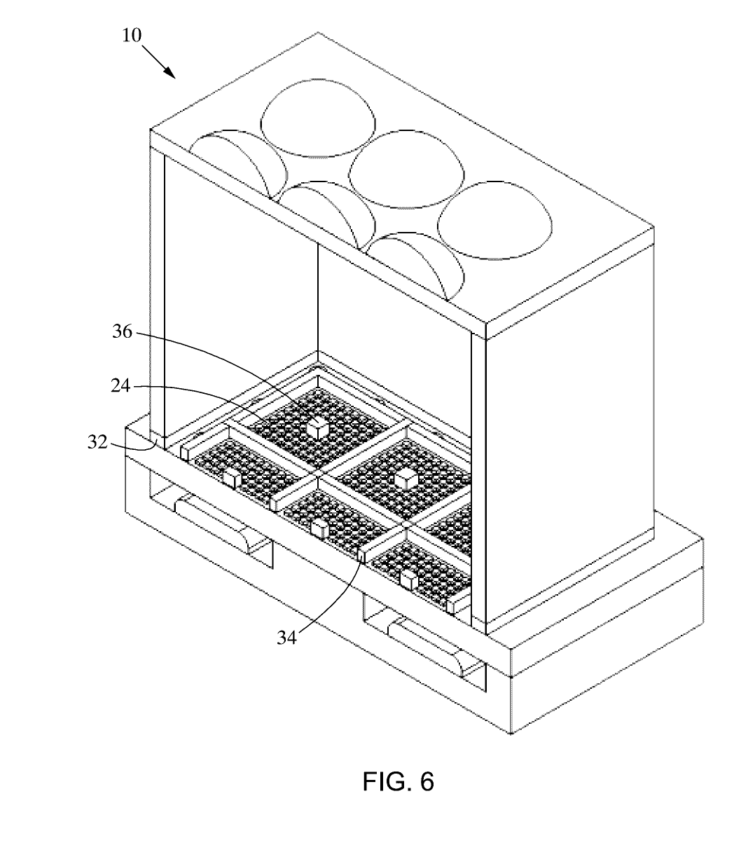

FIG. 6 shows an isometric, cross-sectional view of the thermal imaging device 10 with a portion of the lid substrate removed to illustrate the support structures more clearly. The support structures include dams or walls 34 that support the thin silicon lid substrate around each sub-array 24 of pixels. The support structures may also comprise support posts 36 positioned within the sub-arrays 24 of pixels. This arrangement maximizes the utilization of the available pixels. A bonding ring 32 provides an additional dam or wall feature surrounding the periphery of the FPA 22. The bonding ring 32 is used to form a hermetic fusion bond between the FPA substrate 20 and the silicon lid. In addition to providing mechanical support and forming a hermetic seal, the dam or wall structures 34 may also provide thermal and optical isolation between pixel sub-arrays 24. Since the inter sub-array regions are generally considered “dead space” for the purpose of locating pixels, it is possible to route circuitry for an underlying CMOS chip along these inter sub-array regions, which improves the area usage efficiency of the overall die.

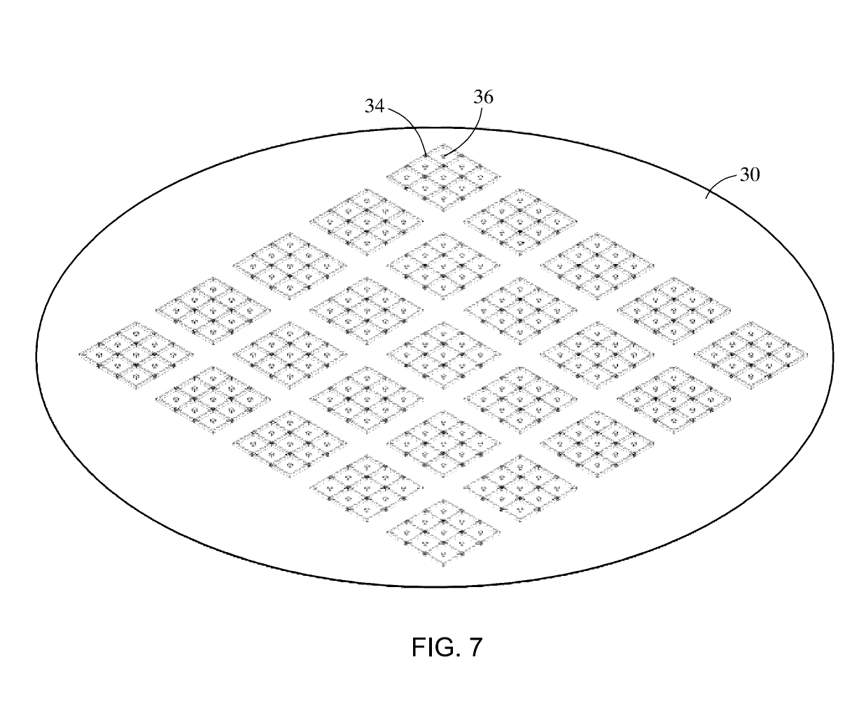

FIG. 7 shows an example in which the support structures are formed on the lid substrate 30. The support posts 36 and bonding walls 34 can be fabricated using the same process steps (e.g., chemical etching of a SOI lid wafer), described in greater detail below. When the lid substrate 30 with the walls 34 and posts 36 is mated against the FPA/ROIC wafer in the bonding process, the walls 34 correspond to the boundaries of the individual sub-arrays of pixels that are defined on the FPA wafer, and seal off each individual sub-array from adjacent sub-arrays. The walls 34 and posts 36 provide periodic support structures for the lid substrate 30 when it is bonded to the FPA wafer, and minimize the bow induced in the lid substrate 30 by a pressure differential on opposite sides of the lid between the ambient pressure and the interior vacuum. Referring to FIG. 3, some embodiments may further include a bonding ring 32 formed on the lid substrate 30. In alternative embodiments, the support structures may be fabricated on the FPA substrate (as either part of the MEMS fabrication process or following the process).

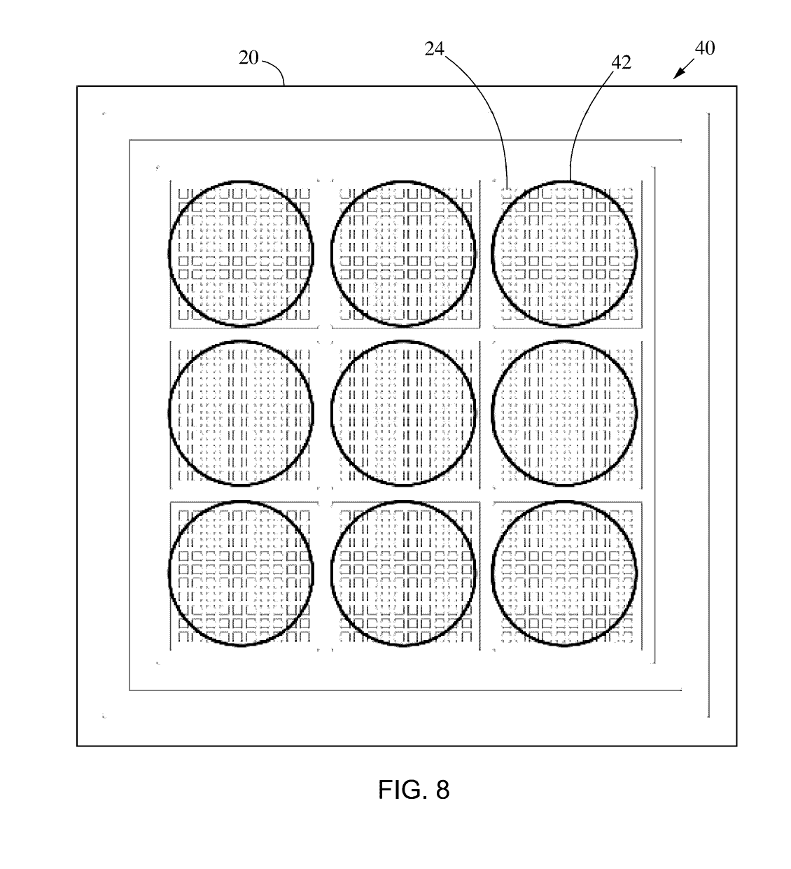

FIG. 8 shows a top plan view of FPA substrate 20 aligned with the lens array 40. Each “lenslet” 42 in the micro-lens array 40 corresponds to a single sub-array 24 on the FPA substrate 20. The thermal imaging system thus comprises a two dimensional matrix of lenslets 42 and corresponding sub-arrays 24 of pixels.

In some embodiments, the micro-lens array 40 is fabricated using chalcogenide glass instead of diamond point turned germanium lenses. Chalcogenide glasses contain a combination of sulfur, selenium or tellurium, are substantially transmissive in the 3 to 5 μm and 8 to 12 μm wavelength range, and have a low glass transition temperature (T_{g}), which allows them to be molded, and create an aspheric or diffractive surface. When germanium is added to the stoichiometry of the glass, the T_{g} increases, making the lens useful across a wider range of temperatures and applications. Some anticipated advantages of the chalcogenide glass include cost reduction derived from using less expensive materials (chalcogenide glass vs. germanium) and employing lower cost batch manufacturing processes (molding vs. diamond point turning), combined with the fact that the cost of lens molding decreases non-linearly with a reduction in lens diameter.

The right advancements in molding technology can enable combinations of aspherical and diffractive elements within a single lens and with a single molding process. The co-molded micro-lenslet array approach combined with the proximity between the lens and the underlying focal plane array enables attachment of the lenses 42 to the FPA substrate 20 at the wafer level in a batch process, thus enabling significant reduction in cost over traditional individual die level camera core assembly. The use of a micro-lens array enables a reduction in the focal length, thereby reducing the form factor of the camera core. A micro-lenslet array approach enables the use of multiple lenslet designs and mounting schemes within the single lens array 40, which can enable compensation for aberrations, thermal drift, large angular fields of view, pixel variation, etc. In some embodiments, two or more of the lenslets 42 have different focal lengths, optical axes, or provide different corrections for optical aberrations.

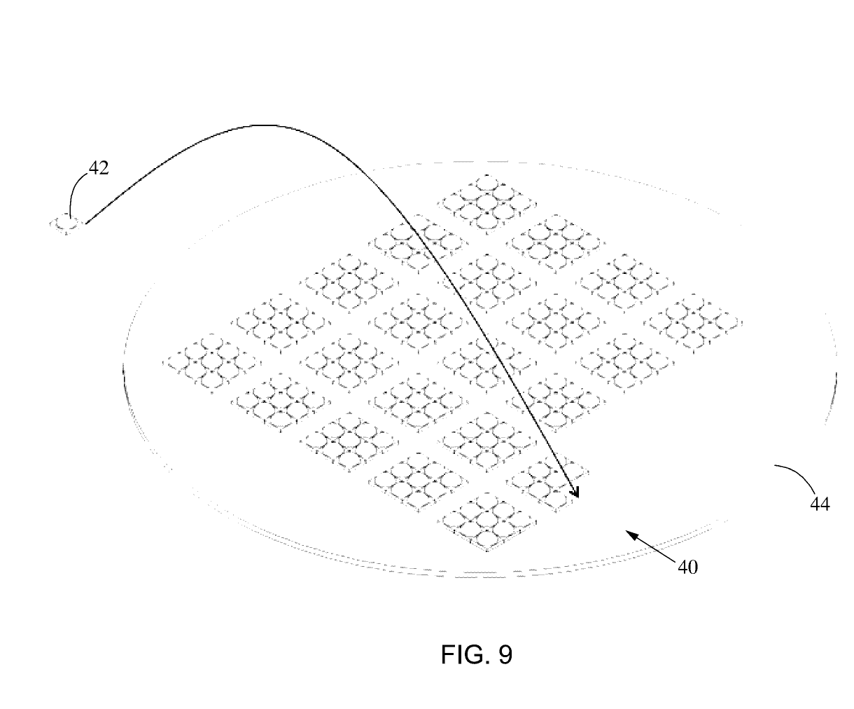

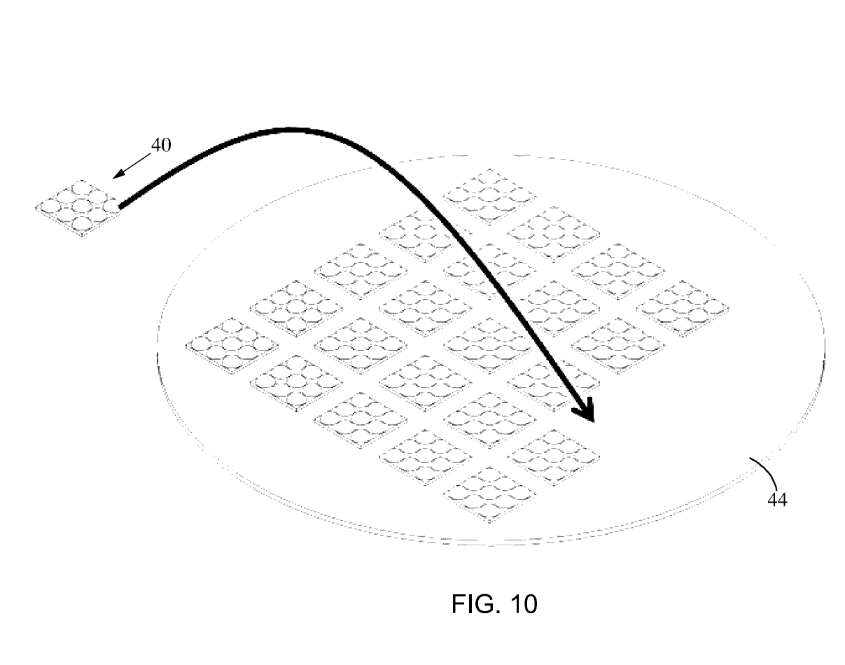

In a typical chalcogenide glass molding process for the lenslets, two halves of a mold are created with the desired surfaces, and heat and pressure are applied to a glass pre-form to obtain the desired lens shape and finish. As shown in FIG. 9, the molding process can be used to fabricate individual lenslets 42 that are subsequently assembled into a micro-lens array 40 on a carrier wafer 44. A carrier wafer 44 may be formed using, for example, silicon, glass, ceramic, metal, or polymer. As shown in FIG. 10, the molding process can alternatively be used to form the entire micro-lens array 40 (e.g., 3×3 lenslets) in a single molding step. The array 40 is subsequently attached to the carrier wafer 44.

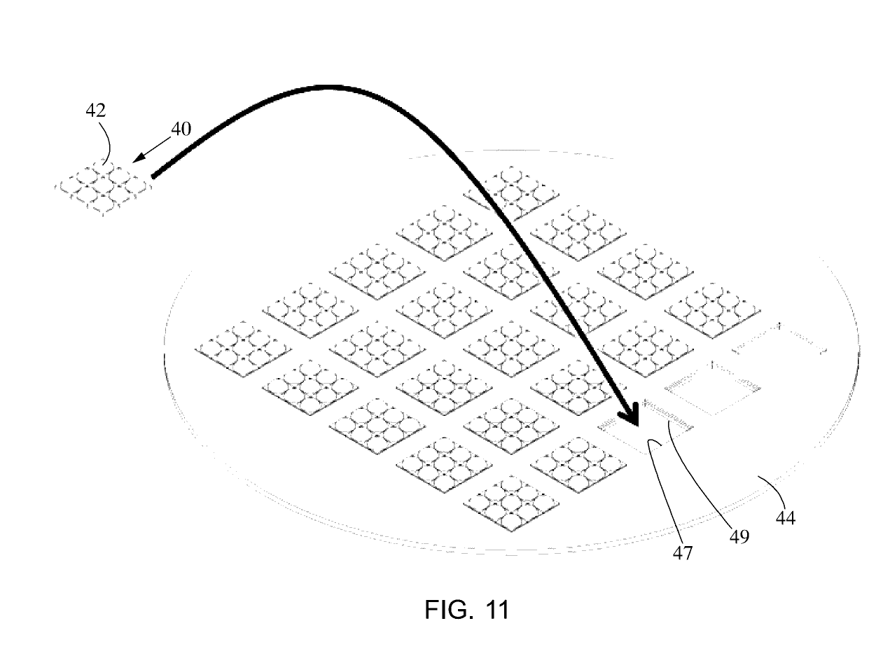

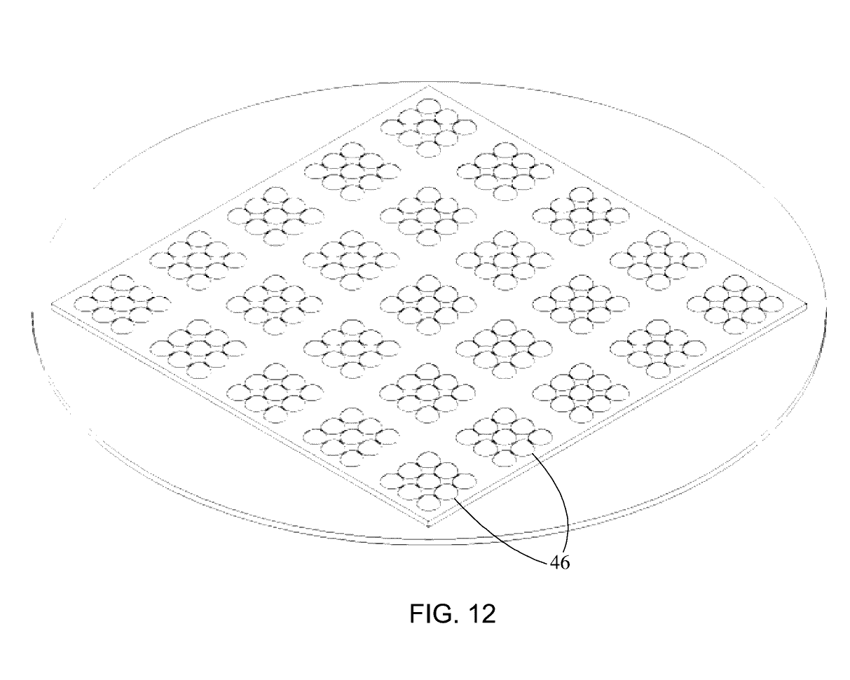

FIG. 11 shows another embodiment in which a carrier wafer 44 has a plurality of windows 47 into which respective lenslet arrays 40 are attached. In other embodiments, each of the windows 47 in the carrier wafer 44 may be sized to receive an individual lenslet 42. The windows 47 may be formed using, for example, a stamping or batch etching process and may further include a ledge 49 to support and align a lenslet array 40 or a lenslet 42. The lenslet arrays 40 or lenslets 42 may be attached to a respective window 47 using, for example, a hermetic solder or fusion bonding process. Another embodiment shown in FIG. 12 illustrates that the molding process can also be used to form a larger wafer comprising multiple lenslet arrays 46. Referring again to FIG. 1, in some embodiments, the carrier wafer is omitted and each lenslet array 40 is attached directly to the standoff structure 38.

The micro-lens array approach has several advantages, such as increased design flexibility within the optical system. One of the limitations in the past of optical lens design for IR systems is the tradeoff between light collection efficiency and the spatial resolution that is obtainable from such a system. By using multiple lenslets 42, each with a small aperture and small focal length, one can decouple the light collection efficiency from the spatial resolution, thus allowing greater design flexibility. By using multiple lenslets 42 each with a smaller aperture, the focal length of the thermal imaging device is reduced significantly. This reduces the form factor and enables wafer level batch assembly of the lens optics to the FPA.

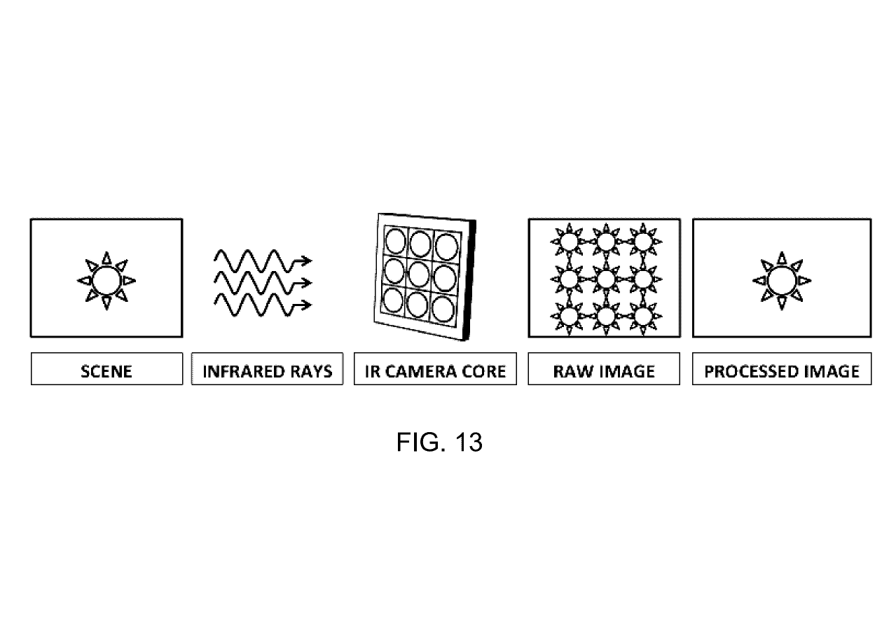

FIG. 13 is a block diagram illustrating the imaging of a scene with a multiple lenslet array and reconstruction of the original image by digital reconstruction and/or super-resolution techniques. It is preferable to use an array of lenses, each with a smaller focal length, rather than a single lens which has a larger focal length. Each micro-lens or “lenslet” covers a sub-array of the FPA as defined above, and individually forms an image on the corresponding pixel sub-array. Thus, with a 3×3 array of micro-lenses covering the FPA, one obtains nine independent images, each of which has a lower resolution than the single image that would have been formed with the single lens addressing the entire pixel array. These lower resolution images can be processed to computationally reconstruct a higher resolution image that approaches the original image.

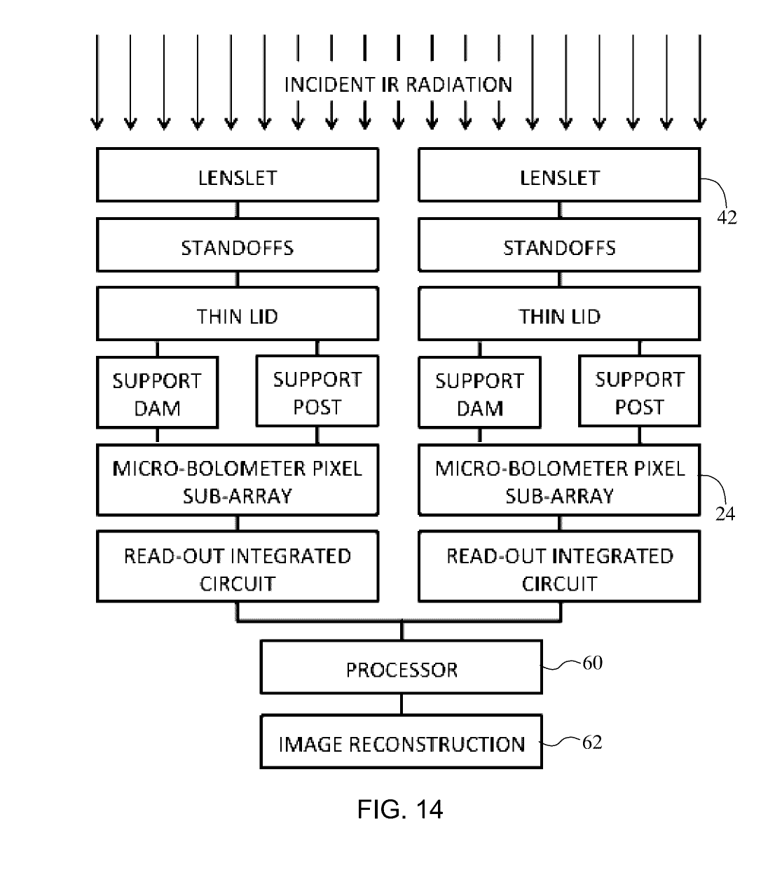

FIG. 14 shows a block diagram of the thermal imaging device, according to some embodiments. The use of a multi-aperture lens system allows variations in the way the individual aperture collects information from a scene, including independent aspheric and diffractive surface design of different lenslets 42 within the micro-lens array, off-axis mounting, diversity in field of view, capture time, digital zoom, and even variations in focal plane. This information enables a processor 60 to perform a wide range of reconstruction analysis with an image reconstruction program 62, which in turn may provide more information about a scene than could be available from a single lens system.

The thermal imaging device can be configured to process scene data from all available pixel sub-arrays 24 to achieve the highest possible resolution, or from a subset of sub-arrays 24 to reduce power consumption, depending on the user's requirements. The use of multiple apertures provides an “oversampling” of the image. Therefore, even if the image from one of the lenslets 42 is defective (either due to mis-calibration of the pixels during field operation, or defects during manufacturing), the resulting digitally reconstructed image can compensate for that based on the information from the remaining lenslets 42. The processor 60 executes an image reconstruction program 62 to construct a higher resolution image from the multiple low-resolution images from the various lenslets 42 in the array. Examples of suitable image reconstruction programs are those used in plenoptic or light-field camera imaging techniques. Plenoptic or light-field camera imaging techniques are known in the art.

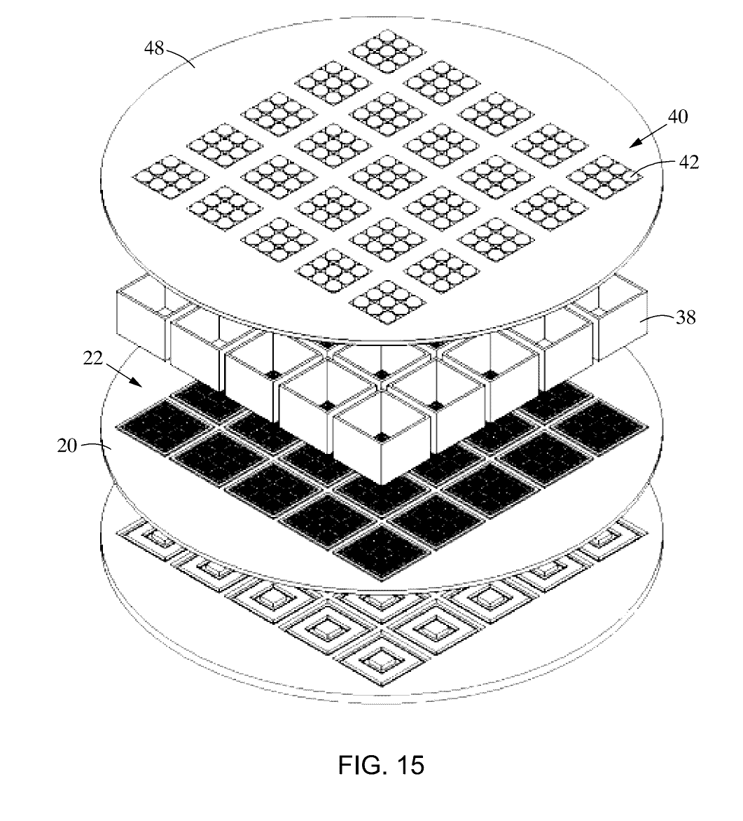

FIG. 15 shows another embodiment of the thermal imaging device in which the silicon lid is omitted. In the case of individually molded lenslets 42 that are assembled into the micro-lens array 40, the lenslet array substrate 48 (e.g., a carrier wafer formed using silicon, glass, ceramic, metal, or polymer) provides the requisite bending stiffness and impermeability to enable a hermetic seal between the FPA substrate 20 and the lenslet array substrate 48 to enclose the FPA 22 in a vacuum in a space between the lens array substrate 48 and the FPA substrate 20. The hermetic seal may be formed, for example using a fusion bonding process. The lenslet array substrate 48 preferably has a thickness in the range of 250 to 2000 μm to impart the requisite bending stiffness to resist excessive deflection across an edge-supported span extending over the entire FPA sub-array die area. A vacuum is maintained in the space containing the FPA 22 between the lenslet array substrate 48 and the FPA substrate 20.

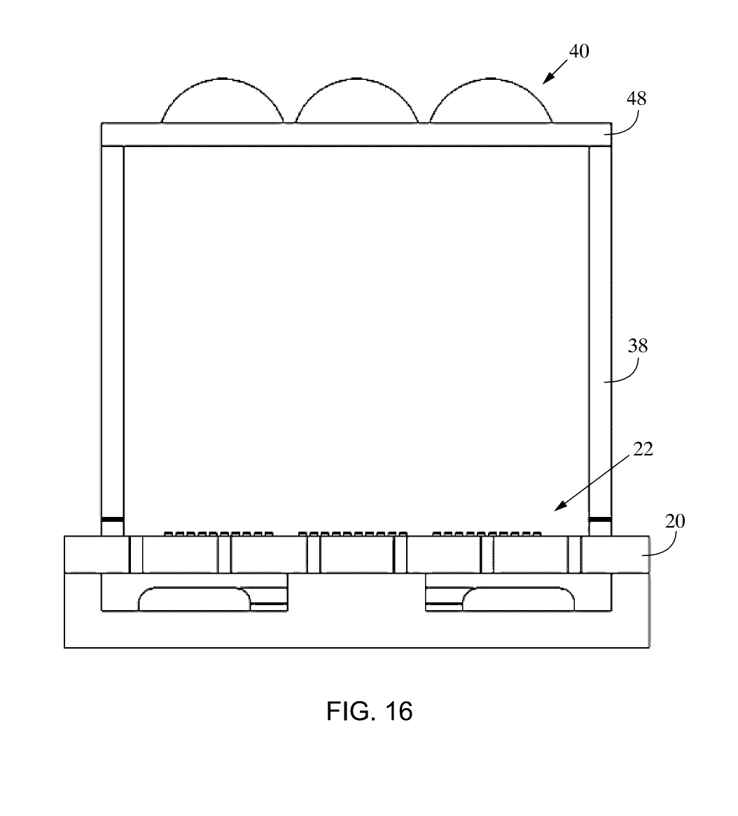

FIG. 16 shows a schematic, cross-sectional view of the thermal imaging device. In some embodiments, the lenslet array substrate 48 may be attached to the spacer or standoff structure 38 that is positioned between the lens and the FPA substrate 20 using, for example, a fusion bonding process. The standoff structure 38 locates the lenslet array 40 at the desired separation from the FPA 22 (e.g., in the range of 2 to 12 mm), aligns the optical axes, and forms the vertical walls around the periphery of the enclosed space containing the FPA 22 between the lens array substrate 48 and the FPA substrate 20.

Optionally, a silicon lid (not shown) may be included to cover the FPA 22. In some embodiments, the pressure of the volume enclosed between the FPA substrate 20 and the silicon lid is substantially equal to the pressure of the volume enclosed between the silicon lid and the lenslet array substrate 48. Thus, the support walls and/or post structures of the first embodiment are no longer needed to prevent excessive deflection of the flexurally compliant, thin silicon lid. Eliminating the need for support structures between the FPA substrate 20 and the silicon lid obviates the need to modify the FPA layout to form inter-sub array exclusion zones for the walls and/or posts.

Referring again to FIG. 2, in some embodiments, there may be a pressure differential across the lid substrate 30. For example, the pressure of the volume enclosed between the FPA substrate 20 and the lid substrate 30 may be less than the pressure of the volume enclosed between the lid substrate 30 and the lenslet array substrate 48, which is in turn less than atmospheric pressure external to the thermal imaging device 10. This embodiment may also obviate the need for support structures and modification of the FPA, while maintaining the FPA in a desired level of vacuum (e.g., at a pressure in the range of 0.1 to 100 mTorr).

Referring again to FIG. 15, in some embodiments, each of the lenslets 42 or lenslet array 40 may be formed using a silicon wafer instead of chalcogenide glass. Preferably the silicon wafer has a thickness in the range of approximately 0.1 to 1 mm. Each lenslet 42 or lenslet array 40 may be formed from the silicon wafer using, for example, one or more photoresist reflow processes followed by one or more deep reactive ion etching (DRIE) steps. Utilizing multiple photolithography and etch processes enables production of the lenslet array 40 where at least one lenslet 42 is substantially different from another one of the lenslets 42. This enables the use of multiple lenslet designs and mounting schemes within a single array, which can enable compensation for optical aberrations, thermal drift, large angular fields of view, pixel variation, etc. In some embodiments, two or more of the lenslets 42 are etched from silicon and have different focal lengths, optical axes and/or provide different corrections for optical aberrations.

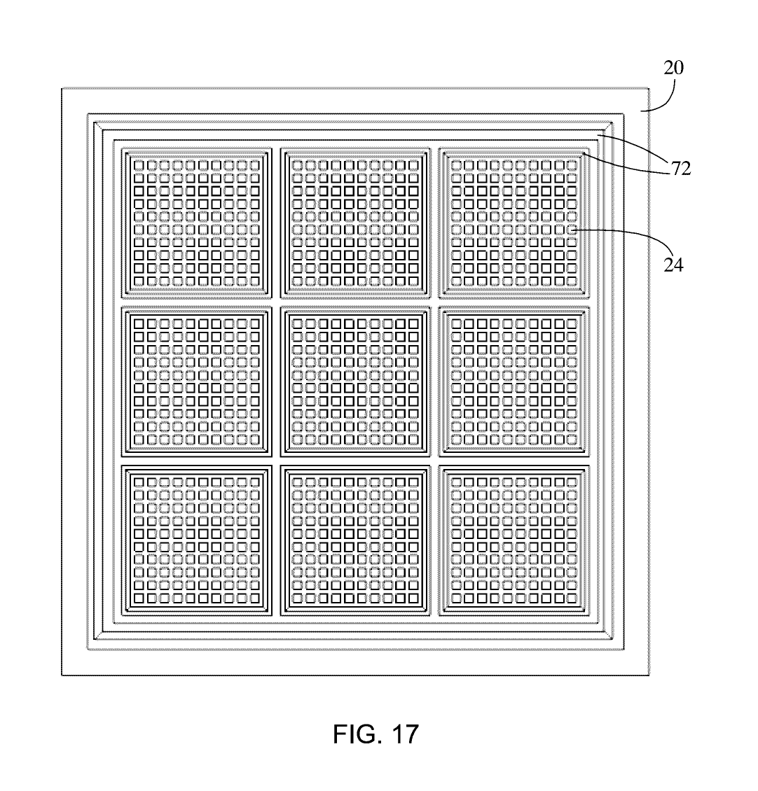

FIG. 17 shows a top plan view of another embodiment in which cavities 72 are formed in the FPA substrate 20, optionally containing getter material. Maintaining the FPA in a desired level of vacuum (for example, 0.1 to 100 mTorr) can be facilitated by increasing the enclosed volume by forming cavities 72 and/or incorporating getter material in one or more cavities 72. The cavities 72 and/or getter material can be located on the process side of the FPA substrate 20 (e.g., around the periphery of the FPA and/or between sub-arrays 24) or on the backside of the FPA substrate 20 and accessed by means of through substrate vias. Both approaches make use of what would otherwise be “dead space” on the FPA substrate 20, thus minimizing the need to modify the FPA layout or increase die size. These techniques are also adaptable to traditional wafer level processing (WLP) approaches.

Various preferred techniques and processes for fabricating the thermal imaging device, according to some embodiments, will now be described. It is useful to first define the candidate FPA to be used for the window packaging approach. The criteria for the candidate FPA include the pixel array size, the resolution, thermistor material, wafer substrate size on which the FPA/ROIC is fabricated, signal-to-noise, frame rate, etc. Additionally, it is useful to specify the requirements from the micro-lens array, including the number of lenslets in the array, the alignment tolerances and mechanical specifications of the lens, and the computation required to reconstruct a full resolution image from the multiple low-resolution images.

Preferably, the SOI lid wafer is fabricated separately so that the silicon lid substrate and the FPA substrate can subsequently be bonded together. A silicon-on-insulator (SOI) wafer essentially comprises a layer of single crystal silicon that is bonded to or grown on a thin layer of silicon-dioxide (SiO₂) which in turn has been grown or deposited on top of a silicon “handle” wafer. The SOI wafer preferably meets certain specifications, including surface roughness, single crystal silicon thickness, defect density, impurity concentration, etc. Table 1 shows some of the specifications of such an SOI wafer.

TABLE 1
Module: SOI wafer specification

| Description | Specification | Method |
|---|---|---|
| SOI thickness | 0.200 um +/− 0.0125 um TTV, 6″ | Spreading Resistance Probing or |
| | manufactured by SIMOX method | optical film thickness measurement, |
| | | 49 pt, 3 mmEE |
| SOI surface | <2 A RMS | 2 × 2 um AFM scan, 3 pt, 3 mmEE |
| roughness | | |
| SOI layer resistivity | >10 ohm-cm | 4 pt probe |
| SOI wafer defects | <15 Light Point Defects at | Dark field defect scanner capable at |
| | >0.15 um | 0.10 um, 3 mmEE |
| | Zero Crystal Originated Particle | |
| | defects | |
| SOI wafer bow | <30 um | Tencor Flexus or equivalent |
| Buried oxide | 0.400 um +/− 5% | Optical film thickness |
| thickness | | measurement, 49 pt |

The next step is to define cavities in the SOI lid wafer, which cavities are typically about 2 to 100 μm deep (with a preferred depth of 5 to 20 μm). Referring again to FIG. 7, the cavities are surrounded by dams or walls 34 at the locations where the lid substrate 30 will be attached to the FPA substrate. Referring again to FIG. 3, when the silicon lid substrate 30 with the walls 34 is mated against the FPA/ROIC substrate 20 in the bonding process, the walls 34 correspond to the boundaries of the individual sub-arrays 24 that are defined on the FPA substrate 20, and seal off each individual sub-array from adjacent sub-arrays 24. These locations also provide periodic “supports” for the lid substrate 30 when it is fully bonded to the FPA substrate 20, and minimize the bow induced in the lid by the pressure differential. Additional “dam” or “post” support structures may optionally be incorporated within each individual sub-array 24 to further mitigate bowing of the lid substrate 30.

The process by which these walls and/or support posts are defined is generally as follows. A thin film (e.g., having a thickness in the range of 5 to 50 μm) of an oxide of silicon (typically known as Undoped Silicate Glass—or USG) is deposited under High Density Plasma (HDP) in a Chemical Vapor Deposition (CVD) reactor. A potential process flow for this process is shown in Table 2.

TABLE 2
Module: TOP OXIDE Deposition

| Description | Specification | Method |
|---|---|---|
| HDP USG | | |
| deposition | | |
| Oxide thickness | 25 kA +/− 6%, 1σ | Optical film thickness |
| Oxide stress | <300 MPa compressive | measurement, 49 pt, |
| Dep/Sputter Ratio | 8-12 | 3 mmEE, blanket test wfr |
| HDP USG | | |
| deposition | | |
| Oxide thickness | 25 kA +/− 6%, 1σ | Optical film thickness |
| Oxide stress | <300 MPa compressive | measurement, 49 pt, |
| Dep/Sputter Ratio | 8-12 | 3 mmEE, blanket test wfr |
| HDP USG | | |
| deposition | | |
| Oxide thickness | 18 kA +/− 6%, 1σ | Optical film thickness |
| Oxide stress | <300 MPa compressive | measurement, 49 pt, |
| Dep/Sputter Ratio | 8-12 | 3 mmEE, blanket test wfr |
| HDP USG Cap | | |
| Oxide thickness | 300 A +/−6%, 1σ | |
| Oxide stress | <300 MPa compressive | Optical film thickness |
| Dep/Sputter Ratio | 8-12 | measurement, 49 pt, |
| Oxide roughness | <5 A RMS | 3 mmEE, blanket test wfr |
| | No gapfill voids, | 2 × 2 um AFM, 3 pt, |
| | no pin-hole | 3 mmEE XSEM, |
| | defects | pattern defect scan |

This layer is then patterned using photolithography techniques, and is chemically etched to form the cavities surrounded by the walls or post structures. The single crystal silicon below the oxide acts as a natural etch stop. A potential process flow is shown in Table 3.

TABLE 3
Module: CAVITY Definition on SOI wafer

| Description | Specification | Method |
|---|---|---|
| CAVITY Photo | | |
| Photoresist | I-line, ~1.5 um | |
| CCD | CCD 2.0 um line | CD SEM, 5 die, array C&E |
| Overlay | <100 nm, x/y component | KLA overlay or equivalent |
| CAVITY Etch | 2.0 um deep, stop on TiN | |
| Profile | 88-90 degrees, smooth sidewall | XSEM die & wfr; C & E |
| End-etch | Endpoint + 20%, all electrodes clear | XSEM die & wfr; C & E |
| CAVITY Etch Clean | | |
| Solvent PR strip | Remove bulk PR | Wet - based bulk PR strip. Rework |
| | | track or equivalent |
| | | Std fab process via clean |
| Polymer strip | Polymer free, specifically feature | EKC 265 or equivalent at 70 C. Fab |
| | sidewalls | std via clean |
| Ash process | 1000 A-4000 A PR removal target | O2, N2, H2O plasma or a |
| | | combination thereof, >200 C.; Fab |
| | | std. ash process |

The pattern is designed such that the walls 34 of the lid substrate 30 mate to the corresponding periphery of the sub-arrays 24 on the FPA substrate 20. This allows the precise mating of the lid substrate 30 to the FPA 22 and bonding at the locations of the walls 34. Each of the cavities in the lid wafer now seals a sub-array 24 of the pixels, and the single crystal silicon becomes the “window” for the transmission of IR.

In embodiments using the lenslet array substrate as part of the vacuum package, the thin SOI lid attach process may be omitted altogether, or the process may differ from the above described substrate- or wafer-level bonding process primarily by the lack of functional support dams, walls or posts within individual FPA die. A series of dams or walls may still formed on the thin lid substrate, but is deliberately designed to be non-hermetic. For example, the dams or walls may not comprise a single, contiguous structure. A standoff structure may be used to form the vertical walls around the periphery of the FPA enclosed in a vacuum.

Several factors are important in the design and sourcing of a micro-lens array fabricated from chalcogenide glass. One of the factors is chromatic aberration. Chalcogenide glass is a dispersive optical medium, which means that its refractive index varies as a function of wavelength. Because the IR wavelengths of interest range from approximately 8 to 14 μm, different wavelengths are focused at different locations, which result in aberrations at the imaging plane. The lens design can use diffractive optical elements to mitigate chromatic aberration, and the appropriate design should be chosen to fit the application. The design of diffractive elements preferably allows one to counteract the dispersion of the chalcogenide glass, thus minimizing any chromatic aberrations.

When a lens system is used across a wide range of ambient temperatures, the focal length of the system changes with temperature due to both a change in the curvature and thickness of the lenses, as well as a change in refractive index with temperature (dn/dT). This is typically compensated for by physically moving the lens along the optical axis. However, when the amount of germanium in the glass is reduced, the refractive index has a reduced dependence on temperature (for example, the dn/dT is less than one fifth of pure germanium), and with additional careful lens design, a system can avoid the use of expensive mechanical assemblies to move the lens system relative to the array. The small relative apertures or f-numbers (F/#s) used in IR lens systems makes them more sensitive to fabrication tolerance variations. One should maintain tight tolerances, surface finishes and material variations and defects for molding not only within a single micro-lens array but also across the entire range of manufactured arrays, as well as in the assembly of the array on to the FPA.

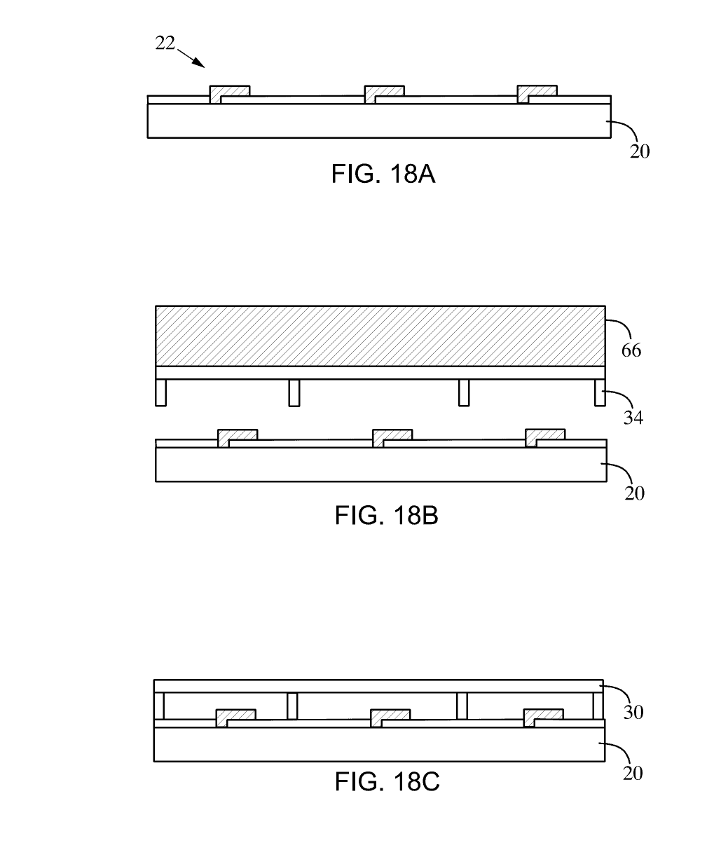

FIGS. 18A-C illustrate a generalized method for bonding the lid substrate 30 to the FPA substrate 20. FIG. 18A shows a FPA/ROIC substrate 20 having a FPA 22 formed thereon. In FIG. 18B, a SOI on handle wafer 66 with walls 34 is bonded to the FPA substrate 20 to enclose the pixels in a vacuum. In FIG. 18C, the handle wafer is removed, leaving the lid substrate 30 as a single crystal silicon packaged window enclosing the pixels in a vacuum between the FPA/ROIC substrate 20 and the lid substrate 30.

Table 4 shows some process steps involved in the preparation of the FPA and SOI lid wafers.

TABLE 4

| | | |
|---|---|---|
| Description | Specification | Method |

Module: SOI Pre-bond Clean

| | | |
|---|---|---|
| SC1 | Remove organics and particles | Low temp, low concentration |
| SC2 | Remove trace metal | Low temp, low concentration |

Module: CMOS wafer Pre-bond Clean

| | | |
|---|---|---|
| Ash target | 500 A PR removal | O2, N2, or H2O plasma, >200 C. |

Module: Bond and Anneal

| | | |
|---|---|---|
| Pre-bond clean | <10 particles at >0.20 um | DI water and megasonic as |
| | | prescribed by bonder Blanket |
| | | wafer particle scan, Tencor |
| | | surfscan or equiv. |
| Plasma activation | SOI wafer only. Zero degree water | N2 plasma, at atmosphere or |
| | contact angle post activation. | vacuum as prescribed by vendor. |
| Bond | Zero bonding voids | Goniometer, bare Si wafer |
| | | Notch aligned. CSAM scan entire |
| | | wafer |
| Anneal | Stabilized bond strength compared | 250 C., 4 hrs, inert atmosphere. Bake |
| | to fully annealed pair | oven or furnace. |
| Bond strength | <10 mm separation | Razor blade and IR inspect. |

Table 5 shows some process steps for the window packaging process.

TABLE 5
Module: Wafer Thinning

| Description | Specification | Method |
|---|---|---|
| Grinding | | |
| Coarse/Fine grind | Grind SOI wafer backside | Capacitance thickness |
| | Target 30 um remaining above BOX | measurement 5 pt, 15 mmEE |
| Polish (Mirror Finish) | <200 A RMS roughness | 2 × 2 um AFM, 3 pt, 3 mmEE |
| Post-polish clean | No grind residue on wafer front and | Ammonia-based brush clean. |
| | back | Fab std post-CMP clean |
| Selective DRIE Si etch | | |
| Breakthrough | Clear of native oxide and organics | High fluorine step to clear |
| Main Si etch rate | >10 um/min, 5%, 1σ | potential micromasking oxide |
| | | and organics |
| Main Si end etch | Etch 30 um Si stop on BOX, EP + 20% | Blanket undoped-poly on oxide |
| | | test wafers |
| Si etch selectivity | >200:1 (silicon to oxide) | Blanket TOX test wafers |
| | >1500 A BOX remaining | Sampled on product wfr |
| Selective wet etch | | |
| Si etch | No micromasking, target 1 um Si | Single wafer spin wet etch, |
| | | SEZ or equiv. NH4OH/NH4F |
| | | based Si etch for micromask |
| | | removal |
| Oxide strip | Clear BOX layer and stop with high | Single wafer spin wet etch, |
| | selectivity to Si | SEZ or equiv. 49% HF, 150 s |
| Defect scan | Dark-field patterned defect | KLA or AIT |
| | inspection | |

Once the SOI on handle wafer has been thinned down to just the “thin” single crystal silicon window, it still may cover all the bond pads on the FPA wafer, and these locations should be exposed to form electrical connections. There are multiple approaches to accomplish this step, of which a chemical etch-through of the single crystal silicon may be the most efficient and cost effective. A sample process flow for this step is shown in Table 6. Another option is mechanical dicing of the regions between the die on the FPA wafer, or to dice the SOI wafer after the lens array has been attached at the wafer level.

TABLE 6
Module: SOI Pad Opening/Wafer Separation

| Description | Specification | Method |
|---|---|---|
| PAD OPENING | | |
| Photo | | |
| Photoresist | >5000 A DUV/BARC on Si | CD SEM, 5 die, array C&E |
| CCD | 0.20 um line & space +/− 0.01 um | KLA overlay or equivalent |
| Overlay | <100 m, x/y component | |
| PAD OPENING | 0.20 um Si, stop on Oxide | ICP Si etcher with CCD control |
| Etch | | |
| Profile | 88-90 degrees, no re-entrant profile, | XSEM die & wfr; C & E |
| | smooth sidewall | |
| End-etch | Timed + 20%, all walls clear | CD SEM, 5 die, array C&E |
| PAD OPENING | | |
| Etch Clean | | |
| PR ash | Strip bulk PR and passivate wafer | Tool in-situ strip/passivation |
| Polymer strip | Polymer free | EKC 265 or equivalent at 70 C. Fab |
| | | std via clean |

To attach the lens array to the FPA, some embodiments of the thermal imaging device contemplate the full substrate or wafer scale attachment of several lens arrays to the respective FPAs at a wafer scale. The process used to assemble the lens array to the FPA package is preferably a standard assembly approach that is similar to what is currently used in the industry. The lens array is preferably assembled at a fixed focal length without moving parts.

The description above illustrates embodiments of the invention by way of example and not necessarily by way of limitation. Accordingly, the scope of the invention should be determined by the following claims and their legal equivalents.

What is claimed is:

1. A thermal imaging device comprising:
a) a focal plane array disposed on a focal plane substrate, wherein the focal plane array comprises a plurality of pixels grouped into sub-arrays of pixels;
b) a lid substrate arranged with the focal plane substrate to enclose the focal plane array in a vacuum;
c) a lens array comprising a plurality of lenslets, wherein each of the lenslets is arranged to focus infrared rays on a respective one of the sub-arrays of pixels;
d) support structures arranged between the lid substrate and the focal plane substrate to support a portion of the lid substrate through which the infrared rays are transmitted; and
e) a readout circuit electrically connected to the pixels.

2. The device of claim 1, wherein the portion of the lid substrate through which the infrared rays are transmitted comprises single crystal silicon having a thickness in the range of 5 to 50 μm.

3. The device of claim 1, wherein the lenslets comprise chalcogenide glass.

4. The device of claim 1, wherein the lenslets comprise etched silicon.

5. The device of claim 1, wherein at least two of the lenslets have different focal lengths.

6. The device of claim 1, wherein at least two of the lenslets have different optical axes.

7. The device of claim 1, wherein at least two of the lenslets provide different corrections for optical aberrations.

8. The device of claim 1, wherein the optical path length from each of the lenslets to the respective sub-array of pixels on which the lenslet focuses the infrared rays is in the range of 2 to 12 mm.

9. The device of claim 1, wherein the vacuum comprises a space in which the pressure is in the range of 0.1 to 100 mTorr.

10. The device of claim 1, wherein the support structures comprise walls positioned between the sub-arrays of pixels such that each of the sub-arrays is divided from adjacent sub-arrays.

11. The device of claim 1, wherein the support structures comprise posts positioned within the sub-arrays.

12. The device of claim 1, further comprising a cavity substrate attached to the focal plane substrate, the cavity substrate having at least one cavity fluidicly connected to the sub-arrays by means of vias in the focal plane substrate.

13. The device of claim 1, wherein the focal plane substrate has at least one cavity in fluid communication with the sub-arrays of pixels.

14. The device of claim 1, further comprising at least one cavity in fluid communication with the sub-arrays of pixels, wherein the cavity contains getter material.

15. The device of claim 1, further comprising at least one processor in communication with the readout circuit, wherein the processor is programmed to construct an image from pixel signals.

16. A thermal imaging device comprising:
a) a focal plane array disposed on a focal plane substrate, wherein the focal plane array comprises a plurality of pixels grouped into sub-arrays of pixels;
b) a lens array substrate comprising a plurality of lenslets, wherein each of the lenslets is arranged to focus infrared rays on a respective one of the sub-arrays of pixels, and wherein the lens array substrate is arranged with the focal plane substrate to enclose the focal plane array in a vacuum in a space between the lens array substrate and the focal plane substrate; and
c) a readout circuit electrically connected to the pixels.

17. The device of claim 16, wherein the pressure in the space is in the range of 0.1 to 100 mTorr.

18. The device of claim 16, further comprising a lid substrate through which the infrared rays are transmitted, wherein the lid substrate is positioned in the space between the lens array substrate and the focal plane substrate.

19. The device of claim 18, wherein a portion of the lid substrate through which the infrared rays are transmitted comprises single crystal silicon having a thickness in the range of 5 to 50 μm.

20. The device of claim 16, wherein the lenslets comprise etched silicon.

21. The device of claim 16, wherein the lenslets comprise chalcogenide glass.

22. The device of claim 16, wherein at least two of the lenslets have different focal lengths.

23. The device of claim 16, wherein at least two of the lenslets have different optical axes.

24. The device of claim 16, wherein at least two of the lenslets provide different corrections for optical aberrations.

25. The device of claim 16, wherein the optical path length from each of the lenslets to the respective sub-array of pixels on which the lenslet focuses the infrared rays is in the range of 2 to 12 mm.

26. The device of claim 16, further comprising a cavity substrate attached to the focal plane substrate, the cavity substrate having at least one cavity fluidicly connected to the sub-arrays by means of vias in the focal plane substrate.

27. The device of claim 16, wherein the focal plane substrate has at least one cavity in fluid communication with the sub-arrays of pixels.

28. The device of claim 16, further comprising at least one cavity in fluid communication with the sub-arrays of pixels, wherein the cavity contains getter material.

29. The device of claim 16, further comprising at least one processor in communication with the readout circuit, wherein the processor is programmed to construct an image from pixel signals.

30. The device of claim 16, wherein the lens array substrate is arranged with the focal plane substrate by means of a standoff structure positioned between the lens array substrate and the focal plane substrate such that the standoff structure forms walls around the periphery of the enclosed space between the lens array substrate and the focal plane substrate.

31. A method for imaging a scene, the method comprising:
a) detecting infrared rays with a focal plane array comprising a plurality of pixels formed on a focal plane substrate, wherein the focal plane array is enclosed in a vacuum in a space between a second substrate and the focal plane substrate, the plurality of pixels are grouped into sub-arrays of pixels, the infrared rays are focused by a lens array comprising a plurality of lenslets, and each of the lenslets is arranged to focus the infrared rays on a respective one of the sub-arrays of pixels; and
b) employing at least one processor to construct an image from pixel signals.

32. The method of claim 31, wherein the pressure in the space is in the range of 0.1 to 100 mTorr.

33. The method of claim 31, wherein the second substrate comprises a lid substrate through which the infrared rays are transmitted, and wherein a portion of the lid substrate through which the infrared rays are transmitted comprises single crystal silicon having a thickness in the range of 5 to 50 μm.

34. The method of claim 33, further comprising the step of supporting the portion of the lid substrate with support structures arranged between the focal plane substrate and the lid substrate.

35. The method of claim 31, wherein the lenslets comprise etched silicon.

36. The method of claim 31, wherein the lenslets comprise chalcogenide glass.

37. The method of claim 31, wherein at least two of the lenslets have different focal lengths.

38. The method of claim 31, wherein at least two of the lenslets have different optical axes.

39. The method of claim 31, wherein at least two of the lenslets provide different corrections for optical aberrations.

40. The method of claim 31, wherein the optical path length from each of the lenslets to the respective sub-array of pixels on which the lenslet focuses the infrared rays is in the range of 2 to 12 mm.

41. The method of claim 31, wherein the second substrate comprises a lens array substrate having the lenslets attached thereto, and wherein the lens array substrate is arranged with the focal plane substrate by means of a standoff structure positioned between the lens array substrate and the focal plane substrate such that the standoff structure forms walls around the periphery of the enclosed space between the lens array substrate and the focal plane substrate.
